(19) United States
(12) Patent Application Publication
(10) Pub. No.: US 2004/0148549 A1
(43) Pub. Date: Jul. 29, 2004

(54) Method for using an alternate performance test to reduce test time and improve manufacturing yield

(76) Inventors: Ram Voorakaranam, Tempe, AZ (US); Abhijit Chatterjee, Marietta, GA (US); Sasikumar Cherubal, Richardson, TX (US); David M. Majernik, Mt. Airy, MD (US)

Correspondence Address: William A. Birdwell, BIRDWELL & JANKE, LLP, Sutie 1400, 1100 SW Sixth Avenue, Portland, OR, 97204, US

(21) Appl. No.: 10/692,586

(22) Filed: Oct. 23, 2003

Related U.S. Application Data
(60) Provisional application No. 60/420,881, filed on Oct. 23, 2002.

(51) Int. Cl. H02H 3/05; H03K 19/003

(52) U.S. Cl. 714/25

(57) ABSTRACT

A method for using an alternate performance test to reduce test time and improve manufacturing yield. The method comprises establishing a specification test limit within which a product would be accepted under specification test criteria and inner and outer alternate test error bounds relative to the specification test limit; initially testing the product with the alternate test; accepting the product if the alternate test result is within the inner alternate test error bound; rejecting the product if the alternate test result is outside the outer alternate test error bound; and retesting the product using the specification test if the alternate test result is on or between the alternate error bounds. On retesting, the product is ordinarily rejected if the specification test result is outside the specification test limits. The method may further comprise modifying a production test to produce a specification test whose guardband is narrower than the production test. The alternate test may provide a reduction of test time from that required by the specification test, and may be a signature test. The method can be used where the acceptability parameter value distribution for the product is peaked, and the specification test has upper and lower test limits.

### RELATED APPLICATIONS

This application is based on and claims priority to U.S. provisional patent application No. 60/420,881, filed Oct. 23, 2002, hereby incorporated by reference in its entirety.

### BACKGROUND OF THE INVENTION

The subject matter of this application relates to performance testing of products during manufacturing to ensure that the products meet performance expectations.

In the manufacture of products, particularly electronic semiconductor integrated circuit devices (“ICs”) and electronic system-on-a-chip devices (“SOCs”), there often is conflict between adequately testing the products to ensure that they meet performance expectations, on the one hand, and minimizing manufacturing costs while maximizing product yield, on the other hand. Although quality control typically is enforced at various stages of the manufacturing process, the most effective way of identifying a defective device is to employ a final performance test, in which a sequence of test steps is applied to the device under test (“DUT”), each producing a value for a parameter of the device specifications. The DUT is considered to be acceptable or defective, that is, to pass or fail the test, based on whether the test values fall within a predetermined range of satisfactory parameter values established for the device specifications. This form of testing is referred to as “specification testing” and the individual tests are referred to as “production tests.”

High quality production tests require accurate and repeatable measurements of the parameters established for the device specifications to ensure that the measured values are as close as possible to the true values and thereby maximize the yield of acceptable products. Not only are such tests time consuming, but where measurement errors are significant, margins of error called “guardbands” are enforced; that is, products whose measured parameters fall outside of a predetermined margin of error from the outer limits of the parameter range are rejected. However, as testing comprises a major component of manufacturing costs, it is desirable to simplify and speed up the testing, which often conflicts with the need for high quality production tests and maximization of the yield of acceptable products.

Specification test time can be reduced in several ways. First, production tests that rarely fail can be deleted or used only on a sampled basis; however, this requires the accumulation and statistical analysis of a lengthy data history. Second, the production test times or the number of trials for measurement averages can be reduced; however, this can compromise test quality or acceptable product yields. Third, a higher speed test apparatus might be used, but this would increase production expense. A fourth approach is to use alternate tests that inherently take less time.

Various alternate tests have been proposed to test products such as analog, mixed-signal and radio frequency electronic circuits in less time than is required by specification testing while minimizing any loss in yield of acceptable products compared to specification testing. Such tests are described in U.S. patent application Ser. No. 09/575,488 entitled METHOD FOR TESTING CIRCUITS, hereby incorporated by reference in its entirety, and in U.S. patent application Ser. No. 09/837,887 entitled METHOD AND APPARATUS FOR LOW COST SIGNATURE TESTING FOR ANALOG AND RF CIRCUITS, also hereby incorporated by reference in its entirety. In particular, it has been shown that if a carefully designed analog transient stimulus is applied to a DUT one or more of the DUT specifications can be mathematically extracted from the corresponding test response. Moreover, while the stimulus may be essentially continuous, such as a modulated waveform, it may also be simple and of short duration, resulting in a significant test-time reduction compared to specification test time. This form of testing is known as “implicit specification testing” or “signature testing.”

Accordingly, it would be desirable to be able to take advantage of the timesaving capability of alternate tests while maintaining the maximum acceptable product yield capabilities of specification testing.

### SUMMARY OF THE INVENTION

The present invention overcomes the aforementioned limitations of product testing by providing a method for using an alternate performance test to test products with at most substantially the same margin of error as a specification test, comprising establishing a specification test limit within which a product would be accepted under specification test criteria and inner and outer alternate test error bounds relative to the specification test limit; initially testing the product with the alternate test; accepting the product if the alternate test result is within the inner alternate test error bound; rejecting the product if the alternate test result is outside the outer alternate test error bound; and retesting the product using the specification test if the alternate test result is on or between the alternate error bounds. On retesting, the product is ordinarily rejected if the specification test result is outside the specification test limits. The method may further comprise modifying a production test to produce a specification test whose guardband is narrower than the production test. The alternate test may provide a reduction of test time from that required by the specification test, and may be a signature test. The method can be used where the parameter value distribution for the product is peaked, and the specification test has upper and lower test limits.

Accordingly, it is a principle objective of the present invention to provide a novel method for testing the performance of products.

The foregoing and other objective, features and advantages of the invention will be more readily understood upon consideration of the following detailed description of the invention, taken in conjunction with the accompanying drawings.

### BRIEF DESCRIPTION OF THE DRAWINGS

FIG. 1 is a histogram of an exemplary distribution of values of a parameter of a DUT, showing upper and lower specification limits and upper and lower specification test limits.

FIG. 2 is a histogram of an exemplary distribution of values of a parameter of a DUT, showing upper and lower specification limits and upper and lower modified specification test limits.

FIG. 3 is plot of measurements using an alternate test against measurements using a specification test, showing a scatter plot of errors in the alternate test relative to the specification test.

FIG. 4 illustrates the relationship of an alternate used in the present invention to a specification test.

FIG. 5 is a flow chart illustrating an exemplary set of steps for implementing the method of the present invention.

### DETAILED DESCRIPTION OF THE INVENTION

In testing of products during manufacturing, particularly in testing ICs and SOCs, test quality metrics relate to how closely the value measured by the actual test matches a true value measured using an “ideal” (error-free) test system. To maximize the yield of acceptable products, it is important that the measured value be as close as possible to the true value while avoiding test escapes, that is, situations where the DUT is actually unacceptable but is passed as acceptable. FIG. 1 shows a histogram of an exemplary distribution 10 of measured values of a parameter of a DUT. The specified parameter value is shown at 12, and actual parameter values are distributed on both sides of the specified value. For ICs and SOCs the value distribution would typically be a normal distribution having a mean at the specified value, where the distribution is peaked; however, the manufacture of some products might produce a different distribution, even one whose derivative does not change sign, and in illustrating the invention with a normal distribution there is no intention of limiting the claims thereto.

An upper specification limit (“USL”) 14 represents the maximum acceptable deviation in one direction from the specified value of a parameter, and a lower specification limit (“LSL”) 16 represents the maximum deviation in the other direction from that specified value. That is, products whose true parameter value lies on or within the upper and lower specification limits are considered acceptable, while products whose true parameter value lies outside those limits are unacceptable. These are the limits that are ordinarily guaranteed on a product specification sheet. However, due to uncertainty in measurement any real specification test has some margin of error 18, comprising upper guardband 20 and lower guardband 22 in the exemplary case of FIG. 1. These guardbands define an upper test limit (“UTL”) 24 and a lower test limit (“LTL”) 26, which are within the USL 14 and LSL 16, respectively. Accordingly, any DUT whose tested parameter value falls outside the UTL or LTL must be rejected, even though the DUT might actually be acceptable, resulting in a yield loss shown by shading 30 in FIG. 1.

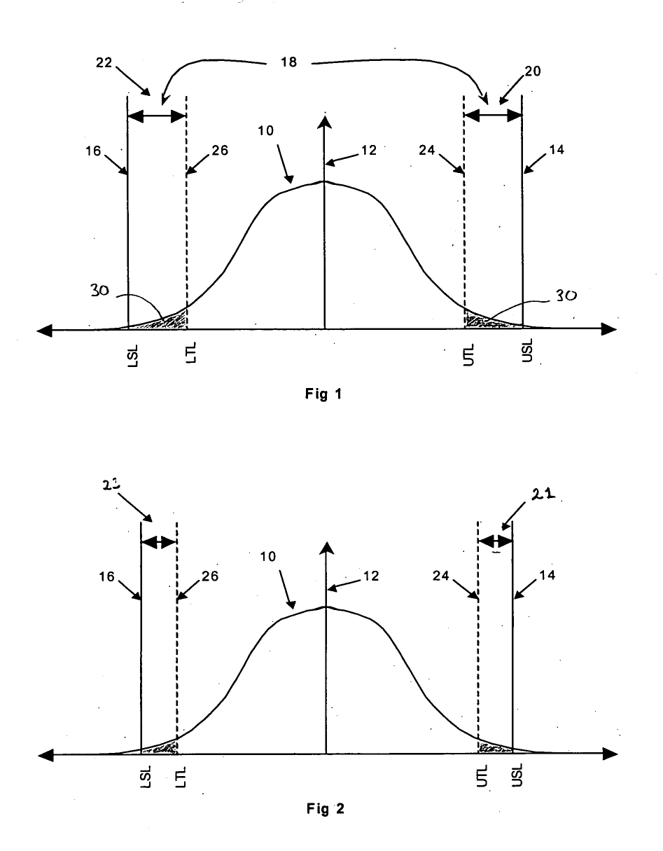

To minimize this yield loss, the widths of the guardbands 20 and 22 need to be minimized. Accordingly, it is may be desirable to modify an existing or standard production test to produce one whose guardbands 21 and 23 are narrower, as shown in FIG. 2. In this description and the claims the term “specification test” is intended to include a single production test or a set of production tests, and to include both standard and modified production tests.

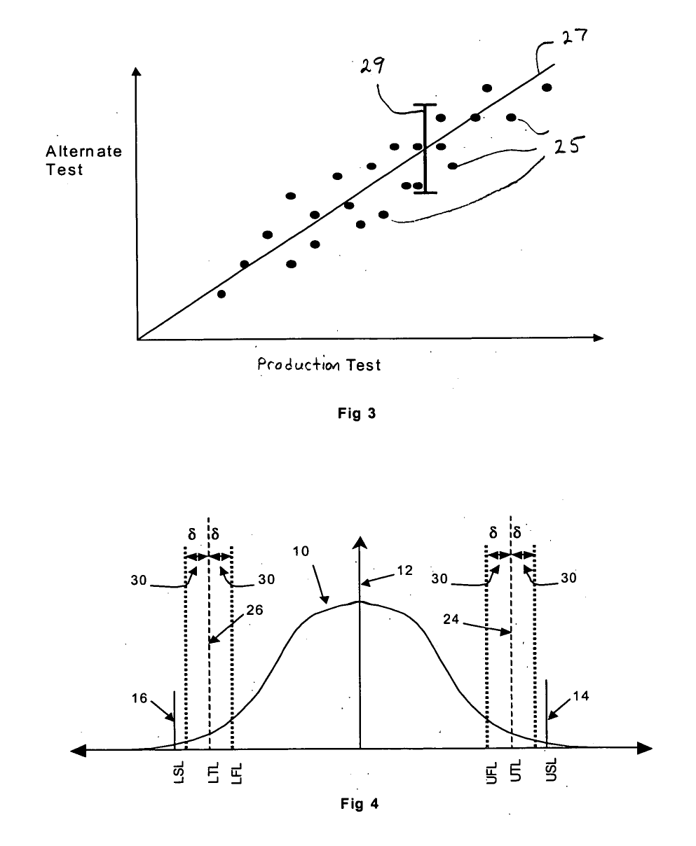

In the present invention an alternate test is employed along with a production test to reduce the time required for testing while providing a yield of acceptable products at least as great as the production test. The production test may be either a standard production test or a modified production test. While the alternate test produces results faster, it is typically not as accurate. Thus, the results of the alternate test vary from those of the production test. This can be seen in FIG. 3, where the alternate test results of a group of products are plotted against the standard or modified production test, depending on which is used. The dots 25 represent data points; the line 27 represents the ideal result if there were no difference between the results of the production test and the alternate test; and the error bar 29 represents the deviation of the alternate test data from the specification test data. That deviation defines inner and outer error bounds δ on respective sides of the specification test limit.

Turning to FIG. 4, the margin of error 30 of the alternate test applies to both sides of both the UTL and LTL established for the production test. Thus, any DUT whose parameter value measured by the alternate test falls inside the inner alternate test error bounds δ will necessarily be acceptable. Any device whose parameter value measured by the alternate test falls between the inner and outer alternate test error bounds of either the UTL or LTL is retested using the production test to determine whether it falls outside the UTL or LTL. Further, any DUT whose parameter value measured by the alternate test falls outside those the outer alternate test error bounds must be considered unsatisfactory and is rejected. In general, it should be understood that the specification test is actually a set of production tests, and that the alternate test is actually a set of performance tests from which the device parameter measurements can be extracted. It is also to be understood that these tests are preferably employed in an automated test system such as would be used in a semiconductor device manufacturing facility to test electronic integrated circuits or electronic systems on a chip.

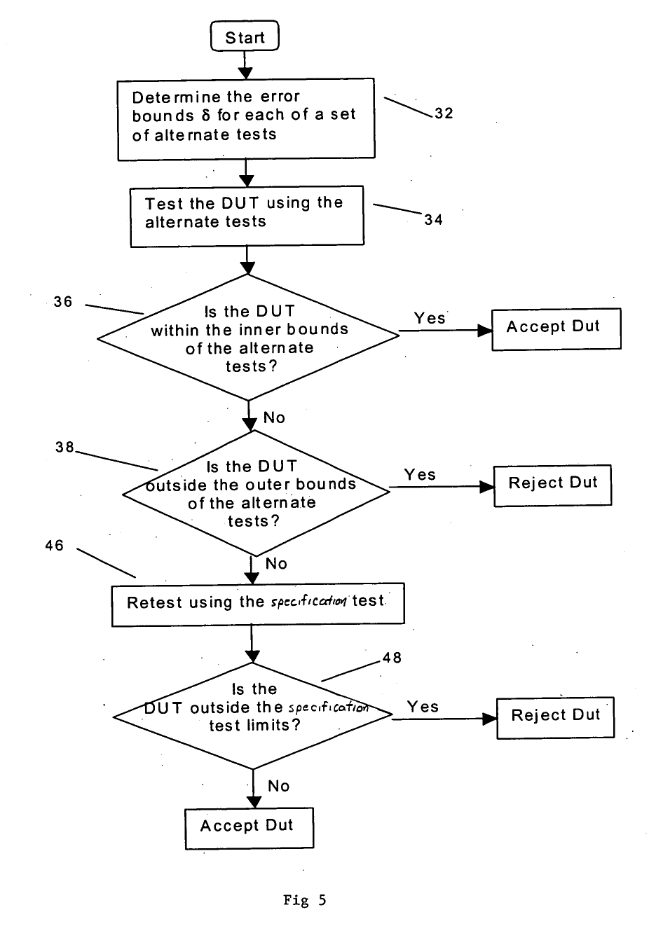

The procedure of the present invention is illustrated by the flow chart of FIG. 5. However, it is to be understood that the flow chart in FIG. 5 is exemplary and that the claims are intended to encompass other combinations or sequences of steps that employ the principles of the invention.

In FIG. 5 the first step 32 of the procedure is to determine the error bounds δ for the each of the set of alternate tests to be employed. These may be chosen, for example, to be an integral number of standard deviations δ inside or outside the upper and lower test limits of the production, or specification, test. These error bounds may be updated before a new device is tested, as appropriate, based on the results of previous measurements of devices. Then, in step 34, a device is tested using the alternate tests.

If, in step 36, the results of measurements of the DUT are found to be within the inner error bounds of the alternate test, the device is accepted, as it must necessarily be within the inner test limits of the specification test. If not, then in step 38, whether the device is outside the outer bounds of the alternate tests is determined. If so, then the device is rejected.

Returning to step 38, if the parameters of the DUT measured by the alternate tests are not outside the outer bounds of the alternate tests, then the results of the alternate tests are between the inner and outer error bounds and the acceptability of the device is indeterminate because its parameters may actually be within the specification test limits, UTL and LTL. To resolve the acceptability of the device, it is then retested, in step 46, using the specification standard test. If, in step 48, the device measurements using the specification test are found to be inside the UTL and LTL, the device is accepted. Otherwise, it is rejected.

The terms and expressions which have been employed in the foregoing specification are used therein as terms of description and not of limitation, and there is no intention, in the use of such terms and expressions, to exclude equivalents of the features shown and described or portions thereof, it being recognized that the scope of the invention is defined and limited only by the claims that follow.

1. A method for using an alternate performance test to test products with at most substantially the same margin of error as a specification test, comprising:
establishing a specification test limit within which a product would be accepted under specification test criteria and inner and outer alternate test error bounds relative to the specification test limit;
initially testing the product with the alternate test;
accepting the product if the alternate test result is within the inner alternate test error bound;
rejecting the product if the alternate test result is outside the outer alternate test error bound; and
retesting the product using the specification test if the alternate test result is on or between the alternate error bounds.

2. The method of claim 1, further comprising modifying a production test to produce a specification test whose guardband is narrower than the production test.

3. The method of claim 2, further comprising rejecting the product if the specification test result is outside the specification test limit.

4. The method of claim 3, comprising rejecting the product if the specification test result is outside the specification test limit.

5. The method of claim 4, wherein the alternate test provides a reduction of test time from that required by the specification test.

6. The method of claim 5, wherein the alternate test is a signature test.

7. The method of claim 6, wherein the parameter value distribution for the product is peaked, and the specification test has upper and lower test limits.

8. The method of claim 3, wherein the parameter value distribution for the product is peaked, and the specification test has upper and lower test limits.

9. The method of claim 3, wherein the alternate test provides a reduction of test time from that required by the specification test

10. The method of claim 9, wherein the alternate test is a signature test.

11. The method of claim 1, wherein the alternate test provides a reduction of test time from that required by the specification test

12. The method of claim 11, wherein the alternate test is a signature test.

13. The method of claim 12, wherein the parameter value distribution for the product is peaked, and the standard test has upper and lower test limits.

14. The method of claim 1, wherein a plurality of products are tested serially and the error bounds are rest one or more times based on previous test results.

15. The method of claim 14 incorporated into an automated product test system.

16. The method of claim 1 incorporated into an automated product test system.

17. The method of claim 1, wherein the standard test comprises a set of individual specification tests for product parameters, and the alternate test comprises a set of individual performance tests from which said parameters may be extracted.

18. The method of claim 1, wherein the products tested are electronic integrated circuits.

19. The method of claim 1, wherein the products tested are electronic systems on a chip.
